(19) United States
(12) Patent Application Publication
(10) Pub. No.: US 2023/0378415 A1
(43) Pub. Date: Nov. 23, 2023

(54) SEMICONDUCTOR LIGHT-EMITTING DEVICE

(71) Applicant: ROHM CO., LTD., Kyoto (JP)

(72) Inventor: Kenya HASHIMOTO, Kyoto (JP)

(21) Appl. No.: 18/296,819

(22) Filed: Apr. 6, 2023

(30) Foreign Application Priority Data
May 18, 2022 (JP) 2022-081594

(51) Int. Cl. H01L 33/62; H01L 23/00

(52) U.S. Cl. CPC H01L 33/62; H01L 24/48; H01L 25/13

(57) ABSTRACT

A semiconductor light-emitting device includes: a substrate with a wiring formed thereon; and a semiconductor light-emitting element. The substrate has first and second main surfaces in its thickness direction, first and second side surfaces in a first direction, third and fourth side surfaces in a second direction, and a first concave groove formed between the first and the third side surfaces. The first side surface has a first edge in contact with the first concave groove, the second side surface has a second edge, and the third side surface has a third edge in contact with the first concave groove and a fourth edge. The wiring includes a first groove wiring formed in the first concave groove and a first distance between the first edge and the third edge is larger than a second distance between the second edge and the fourth edge.

### CROSS-REFERENCE TO RELATED APPLICATION

This application is based upon and claims the benefit of priority from Japanese Patent Application No. 2022-081594, filed on May 18, 2022, the entire contents of which are incorporated herein by reference.

### TECHNICAL FIELD

The present disclosure relates to a semiconductor light-emitting device.

### BACKGROUND

Semiconductor light-emitting devices are widely used as light source devices for electronic equipment and the like. In the related art, an example of a semiconductor light-emitting device is disclosed. In the related art, the semiconductor light-emitting device includes a substrate, an LED chip (semiconductor light-emitting element), and a resin package (sealing resin). The substrate has a front surface, a back surface, and four side surfaces. The front surface faces one side in a thickness direction of the substrate. The back surface faces one side in the thickness direction of the substrate. The four side surfaces have a substantially rectangular shape when viewed in the thickness direction of the substrate. The substrate is provided with a pair of electrodes that form a conductive path to the LED chip. The LED chip is mounted on the front surface of the substrate. The resin package covers the LED chip and transmits light from the LED chip.

In the related art, the semiconductor light-emitting device is provided with concave grooves formed at the four corners of the substrate and extending in the thickness direction. A cross-sectional shape of each of these concave grooves perpendicular to the thickness direction is a substantially quarter-circular shape. A concave groove wiring made of a plated layer or the like is formed in each concave groove, and each concave groove wiring is electrically connected to one of the pair of electrodes. When the semiconductor light-emitting device having the above-described structure is used, it is mounted on a mounting substrate. The semiconductor light-emitting device described above may be used as a so-called side-view type light source that emits light in a direction parallel to the front surface of the mounting substrate. In this case, the semiconductor light-emitting device is mounted on the mounting substrate in such a manner that the side surface of the substrate faces the mounting substrate. In the semiconductor light-emitting device used as the side-view type light source, the concave groove wiring formed in the concave groove and the mounting substrate are bonded together via a bonding portion such as solder.

These days, products such as the semiconductor light-emitting device are required to be further reduced in size. In a case where reduction in a product size of the above-described semiconductor light-emitting device is promoted, the dimensions of the concave grooves at the four corners of the substrate are reduced. As a result, in a case where the above-described semiconductor light-emitting device in the related art is used as the side-view type light source, a sufficient bonding portion may not be formed with respect to the mounting substrate, so there is a concern that a mounting strength on the mounting substrate may decrease.

### SUMMARY

Some embodiments of the present disclosure provide a semiconductor light-emitting device that is suitable for improving a mounting strength and reducing a size of the device.

According to an embodiment of the present disclosure, a semiconductor light-emitting device includes: a substrate; a wiring formed on the substrate; and a semiconductor light-emitting element, wherein the substrate has a first main surface facing one side in a thickness direction of the substrate, a second main surface facing the other side in the thickness direction, a first side surface facing one side in a first direction orthogonal to the thickness direction, a second side surface facing the other side in the first direction, a third side surface facing one side in a second direction orthogonal to both the thickness direction and the first direction, and a first concave groove formed between the first side surface and the third side surface and recessed from the first side surface and the third side surface, wherein the first side surface has a first edge located on the one side in the second direction and in contact with the first concave groove, wherein the second side surface has a second edge located on the one side in the second direction, wherein the third side surface has a third edge located on the one side in the first direction and in contact with the first concave groove, and a fourth edge located on the other side in the first direction, wherein the semiconductor light-emitting device is supported on the first main surface, wherein the wiring includes a first groove wiring formed in the first concave groove, and wherein a first distance between the first edge and the third edge is larger than a second distance between the second edge and the fourth edge.

Other features and advantages of the present disclosure will become more apparent from the detailed description that follows with reference to the accompanying drawings.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor light-emitting device according to a first embodiment of the present disclosure.

FIG. 2 is a front view showing the semiconductor light-emitting device according to the first embodiment of the present disclosure.

FIG. 3 is a left side view showing the semiconductor light-emitting device according to the first embodiment of the present disclosure.

FIG. 4 is a bottom view showing the semiconductor light-emitting device according to the first embodiment of the present disclosure.

FIG. 5 is a cross-sectional view taken along line V-V in FIG. 1.

FIG. 6 is a cross-sectional view taken along line VI-VI in FIG. 1.

FIG. 7 is a cross-sectional view taken along line VII-VII in FIG. 1.

FIG. 8 is a plan view showing an example of a manufacturing process of the semiconductor light-emitting device according to the first embodiment of the present disclosure.

FIG. 9 is a front view showing an example of a mounted state of the semiconductor light-emitting device according to the first embodiment of the present disclosure.

FIG. 10 is a plan view showing a semiconductor light-emitting device according to a second embodiment of the present disclosure.

FIG. 11 is a front view showing the semiconductor light-emitting device according to the second embodiment of the present disclosure.

FIG. 12 is a left side view of the semiconductor light-emitting device according to the second embodiment of the present disclosure.

FIG. 13 is a plan view showing an example of a manufacturing process of the semiconductor light-emitting device according to the second embodiment of the present disclosure.

FIG. 14 is a front view showing an example of a mounted state of the semiconductor light-emitting device according to the second embodiment of the present disclosure.

FIG. 15 is a plan view showing a semiconductor light-emitting device according to a third embodiment of the present disclosure.

FIG. 16 is a front view showing the semiconductor light-emitting device according to the third embodiment of the present disclosure.

FIG. 17 is a left side view showing the semiconductor light-emitting device according to the third embodiment of the present disclosure.

FIG. 18 is a plan view showing an example of a manufacturing process of the semiconductor light-emitting device according to the third embodiment of the present disclosure.

FIG. 19 is a front view showing an example of a mounted state of the semiconductor light-emitting device according to the third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the drawings.

In the present disclosure, the terms “first,” “second,” “third,” and the like are used merely as labels and are not necessarily intended to append an order to their objects.

In the present disclosure, the phrases “a certain thing A is formed in another certain thing B” and “a certain thing A is formed on another certain thing B” include, unless otherwise specified, “a certain thing A is directly formed in another certain thing B” and “a certain thing A is formed on another certain thing B with another thing interposed between the certain thing A and the another certain thing B.” Similarly, the phrases “a certain thing A is placed in another certain thing B” and “a certain thing A is placed on another certain thing B” include, unless otherwise specified, “a certain thing A is directly placed in another certain thing B” and “a certain thing A is placed in another certain thing B with another thing interposed between the certain thing A and the another certain thing B.” Similarly, the phrase “a certain thing A is located on another certain thing B” includes, unless otherwise specified, “a certain thing A is located on another certain thing B while the certain thing A is in contact with the another certain thing B” and “a certain thing A is located on another certain thing B with another thing interposed between the certain thing A and the another certain thing B.” In addition, the phrase “a certain thing A overlaps with another certain thing B when viewed in a certain direction” includes, unless otherwise specified, “a certain thing A overlaps entirely with another certain thing B” and “a certain thing A overlaps partially with another certain thing B.” In addition, in the present disclosure, the phrase “a certain surface A faces in a direction B (one side or the other side thereof)” is not limited to a case where an angle of the surface A with respect to the direction B is 90 degrees, but includes a case where the surface A is tilted with respect to the direction B. In addition, the phrase “a certain thing A is supported by another certain thing B” includes, unless otherwise specified, “a certain thing A is directly supported by another certain thing B” and “a certain thing A is supported by another certain thing B with another thing interposed between the certain thing A and the another certain thing B.”

### First Embodiment

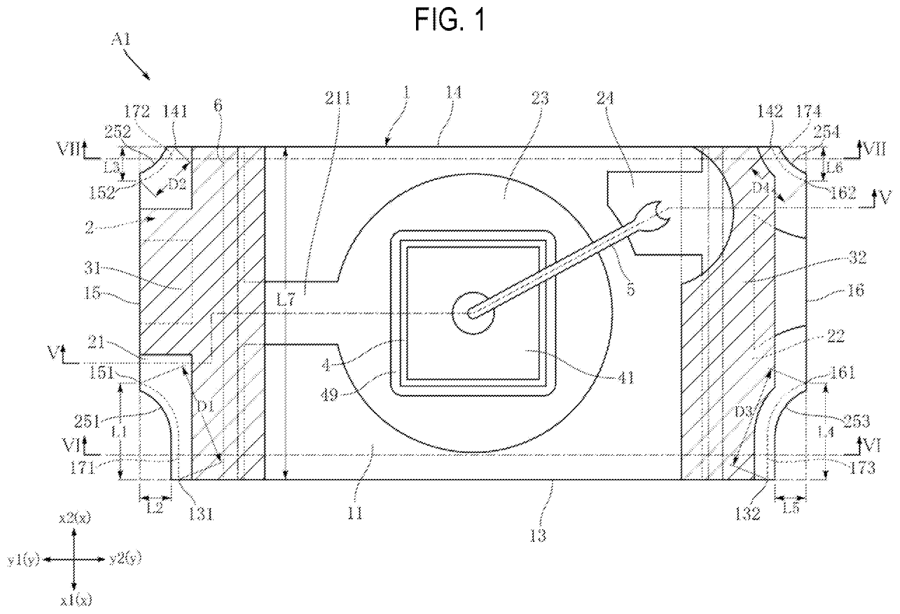

FIGS. 1 to 7 show a semiconductor light-emitting device according to a first embodiment of the present disclosure. The semiconductor light-emitting device A1 of the present embodiment includes a substrate 1, a wiring 2, a first insulating film 31, a second insulating film 32, a semiconductor light-emitting element 4, a wire 5, a sealing resin 6, and an insulating film 7.

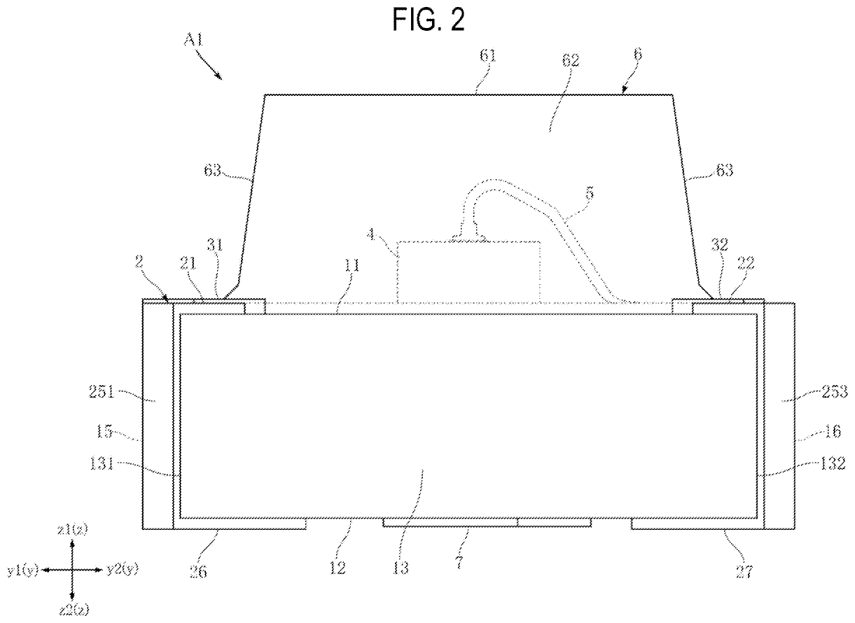

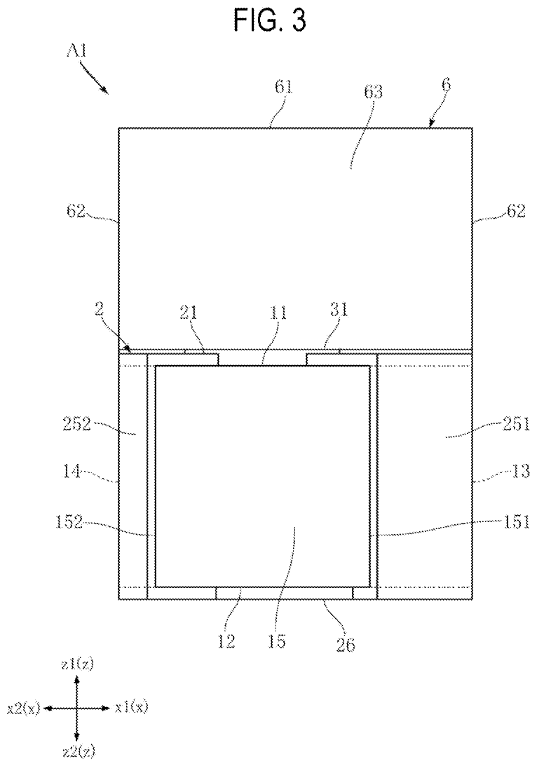

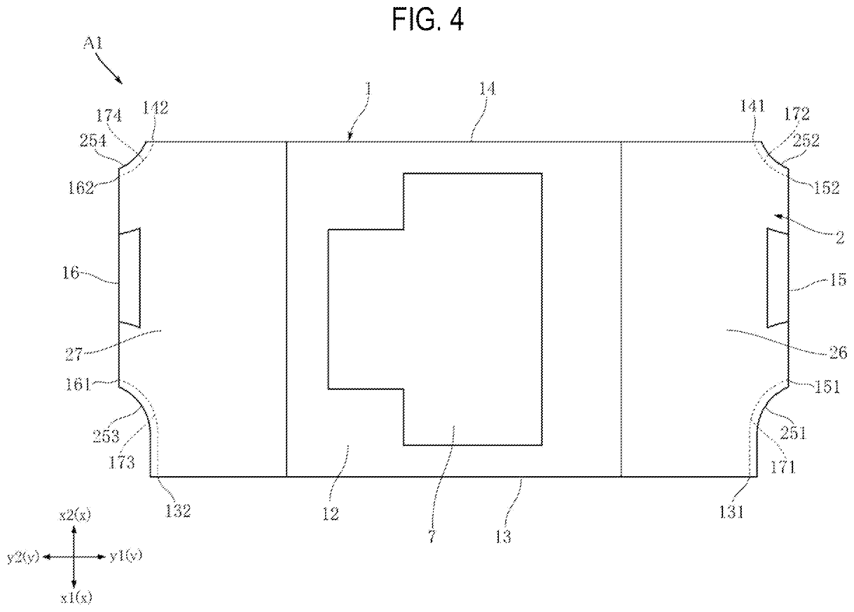

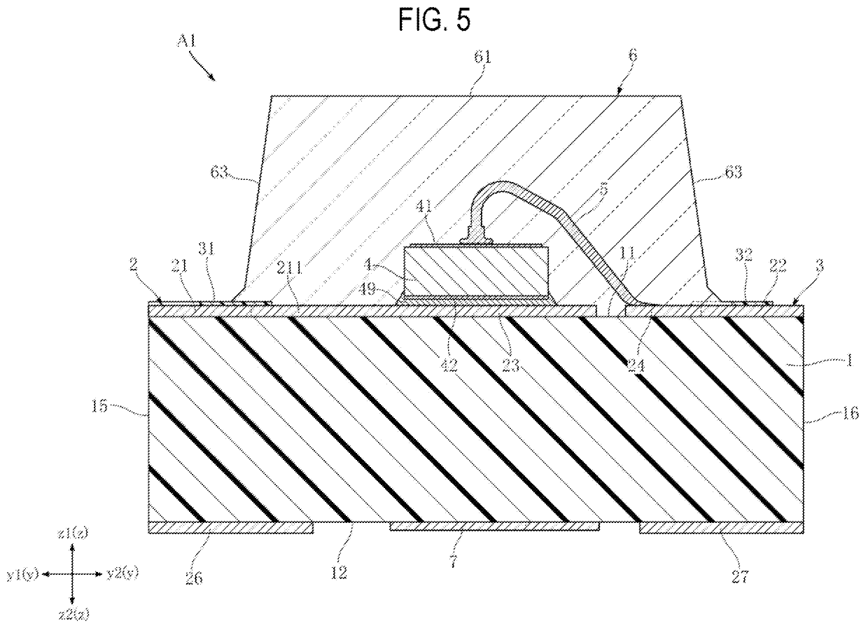

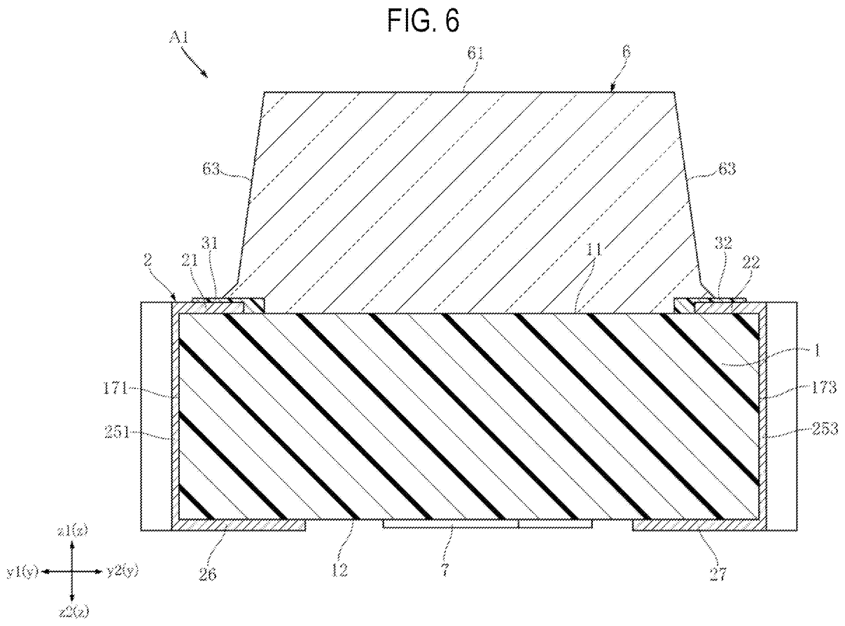

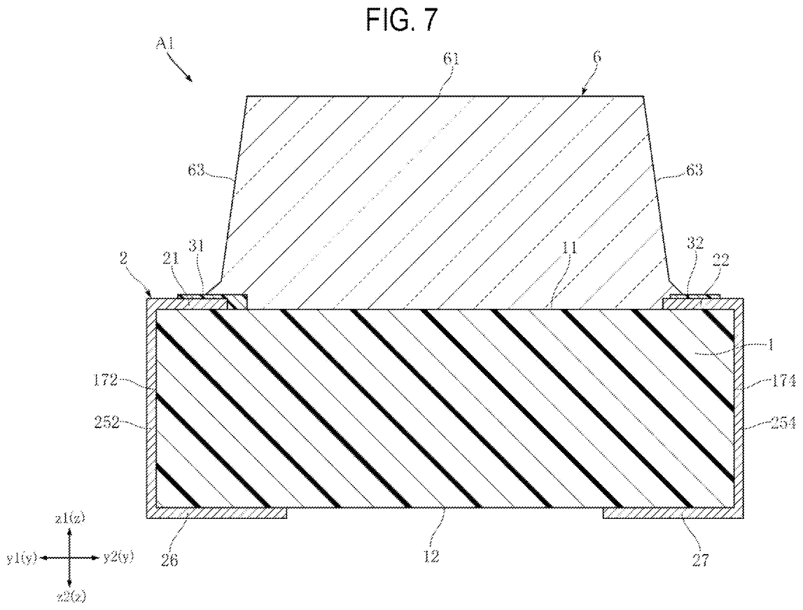

FIG. 1 is a plan view showing the semiconductor light-emitting device A1. FIG. 2 is a front view of the semiconductor light-emitting device A1. FIG. 3 is a left side view of the semiconductor light-emitting device A1. FIG. 4 is a bottom view of the semiconductor light-emitting device A1. FIG. 5 is a cross-sectional view taken along line V-V in FIG. 1. FIG. 6 is a cross-sectional view taken along line VI-VI in FIG. 1. FIG. 7 is a cross-sectional view taken along line VII-VII in FIG. 1. Further, FIG. 1 is shown as penetrating the sealing resin 6 for the sake of convenience of understanding.

In the description of the semiconductor light-emitting device A1, a thickness direction (a plan view direction) of the semiconductor light-emitting device A1 is an example of the “thickness direction” in the present disclosure and is referred to as a “thickness direction z.” A direction orthogonal to the thickness direction z is an example of the “first direction” in the present disclosure and is referred to as a “first direction x.” A direction orthogonal to both the thickness direction z and the first direction x is an example of the “second direction” in the present disclosure and is referred to as a “second direction y.” In addition, in FIG. 1, the lower side of the figure is an example of “one side in the first direction” in the present disclosure and is referred to as a “first direction one side x1,” and the upper side of the figure is an example of “the other side in the first direction” in the present disclosure and is referred to as a “first direction other side x2.” In FIG. 1, the left side of the figure is an example of “one side in the second direction” in the present disclosure and is referred to as a “second direction one side y1,” and the right side of the figure is an example of “the other side in the second direction” in the present disclosure and is referred to as a “second direction other side y2.” In FIG. 2, the upper side of the figure is an example of “one side in the thickness direction” in the present disclosure and is referred to as a “thickness direction one side z1,” and the lower side of the figure is an example of “the other side in the thickness direction” in the present disclosure and is referred to as a “thickness direction other side z2.” As shown in FIG. 1, the semiconductor light-emitting device A1 has a substantially rectangular shape when viewed in the thickness direction z. The size of the semiconductor light-emitting device A1 is not particularly limited.

The substrate 1 has a rectangular parallelepiped shape and includes, for example, an insulating material such as glass epoxy resin. The size of the substrate 1 is not particularly limited and is, for example, about 0.8 mm in the first direction x, about 1.6 mm in the second direction y, and about 0.6 mm in the thickness direction z.

The substrate 1 has a first main surface 11, a second main surface 12, a first side surface 13, a second side surface 14, a third side surface 15, and a fourth side surface 16. In the present embodiment, the substrate 1 further has a first concave groove 171, a second concave groove 172, a third concave groove 173, and a fourth concave groove 174. The first main surface 11 is a plane facing the thickness direction one side z1. The second main surface 12 is a plane facing the thickness direction other side z2. The first side surface 13 is located between the first main surface 11 and the second main surface 12 in the thickness direction z and faces the first direction one side x1. The second side surface 14 is located between the first main surface 11 and the second main surface 12 in the thickness direction z and faces the first direction other side x2. The third side surface 15 is located between the first main surface 11 and the second main surface 12 in the thickness direction z and faces the second direction one side y1. The fourth side surface 16 is located between the first main surface 11 and the second main surface 12 in the thickness direction z and faces the second direction other side y2.

The first concave groove 171, the second concave groove 172, the third concave groove 173, and the fourth concave groove 174 are provided at four corners of the substrate 1 when viewed in the thickness direction z. Specifically, the first concave groove 171 is formed between the first side surface 13 and the third side surface 15 and is recessed from the first side surface 13 and the third side surface 15. The second concave groove 172 is formed between the second side surface 14 and the third side surface 15 and is recessed from the second side surface 14 and the third side surface 15. The third concave groove 173 is formed between the first side surface 13 and the fourth side surface 16 and is recessed from the first side surface 13 and the fourth side surface 16. The fourth concave groove 174 is formed between the second side surface 14 and the fourth side surface 16 and is recessed from the second side surface 14 and the fourth side surface 16. Each of the first concave groove 171, the second concave groove 172, the third concave groove 173, and the fourth concave groove 174 reaches the first main surface 11 and the second main surface 12 in the thickness direction z.

In the present embodiment, a cross-sectional shape of the first concave groove 171 perpendicular to the thickness direction z is a substantially quarter circular shape and a line segment connected thereto. Further, like the first concave groove 171, a cross-sectional shape of the third concave groove 173 perpendicular to the thickness direction z is a substantially quarter circular shape and a line segment connected thereto. On the other hand, a cross-sectional shape of each of the second concave groove 172 and the fourth concave groove 174 perpendicular to the thickness direction z is a substantially quarter circular shape.

As shown in FIGS. 1, 2, and 4, the first side surface 13 has a first edge 131 and a fifth edge 132. The first edge 131 is an edge located on the second direction one side y1 of the first side surface 13 and extends along the thickness direction z. The fifth edge 132 is an edge located on the second direction other side y2 of the first side surface 13 and extends along the thickness direction z. In the present embodiment, the first edge 131 is in contact with the first concave groove 171 and also serves as a boundary between the first side surface 13 and the first concave groove 171. Further, the fifth edge 132 is in contact with the third concave groove 173 and also serves as a boundary between the first side surface 13 and the third concave groove 173.

As shown in FIGS. 1 and 4, the second side surface 14 has a second edge 141 and a sixth edge 142. The second edge 141 is an edge located on the second direction one side y1 of the second side surface 14 and extends along the thickness direction z. The sixth edge 142 is an edge located on the second direction other side y2 of the second side surface 14 and extends along the thickness direction z. In the present embodiment, the second edge 141 is in contact with the second concave groove 172 and also serves as a boundary between the second side surface 14 and the second concave groove 172. Further, the sixth edge 142 is in contact with the fourth concave groove 174 and also serves as a boundary between the second side surface 14 and the fourth concave groove 174.

As shown in FIGS. 1, 3, and 4, the third side surface 15 has a third edge 151 and a fourth edge 152. The third edge 151 is an edge located on the first direction one side x1 of the third side surface 15 and extends along the thickness direction z. The fourth edge 152 is an edge located on the first direction other side x2 of the third side surface 15 and extends along the thickness direction z. In the present embodiment, the third edge 151 is in contact with the first concave groove 171 and also serves as a boundary between the third side surface 15 and the first concave groove 171. Further, the fourth edge 152 is in contact with the second concave groove 172 and also serves as a boundary between the third side surface 15 and the second concave groove 172.

As shown in FIGS. 1 and 4, the fourth side surface 16 has a seventh edge 161 and an eighth edge 162. The seventh edge 161 is an edge located on the first direction one side x1 of the fourth side surface 16 and extends along the thickness direction z. The eighth edge 162 is an edge located on the first direction other side x2 of the fourth side surface 16 and extends along the thickness direction z. In the present embodiment, the seventh edge 161 is in contact with the third concave groove 173 and also serves as a boundary between the fourth side surface 16 and the third concave groove 173. Further, the eighth edge 162 is in contact with the fourth concave groove 174 and also serves as a boundary between the fourth side surface 16 and the fourth concave groove 174.

As shown in FIG. 1, a distance (first distance D1) between the first edge 131 of the first side surface 13 and the third edge 151 of the third side surface 15 is larger than a distance (second distance D2) between the second edge 141 of the second side surface 14 and the fourth edge 152 of the third side surface 15. In the first concave groove 171, a first dimension L1, which is a depth dimension from the first side surface 13 to the first direction other side x2, is larger than a second dimension L2 which is a depth dimension from the third side surface 15 to the second direction other side y2. Further, the first dimension L1 is larger than a third dimension L3 which is a depth dimension from the second side surface 14 to the first direction one side x1 in the second concave groove 172.

A ratio of the depth dimension (the first dimension L1) of the first concave groove 171, from the first side surface 13 to the first direction other side x2, to a length (seventh dimension L7) of the first main surface 11 in the first direction x is, for example, in a range of 0.15 to 0.4 times. In the example shown in FIG. 1, the ratio of the first dimension L1 to the seventh dimension L7 is about 0.29 times.

As shown in FIG. 1, a distance (third distance D3) between the fifth edge 132 of the first side surface 13 and the seventh edge 161 of the fourth side surface 16 is larger than a distance (fourth distance D4) between the sixth edge 142 of the second side surface 14 and the eighth edge 162 of the fourth side surface 16. In the third concave groove 173, a fourth dimension L4, which is a depth dimension from the first side surface 13 to the first direction other side x2, is larger than a fifth dimension L5 which is a depth dimension from the fourth side surface 16 to the second direction one side y1. Further, the fourth dimension L4 is larger than a sixth dimension L6 which is a depth dimension from the second side surface 14 to the first direction one side x1 in the fourth concave groove 174.

A ratio of the depth dimension (the fourth dimension L4) of the third concave groove 173, from the first side surface 13 to the first direction other side x2, to the length (the seventh dimension L7) of the first main surface 11 in the first direction x is, for example, in a range of 0.15 to 0.4 times. In the example shown in FIG. 1, the ratio of the fourth dimension L4 to the seventh dimension L7 is about 0.29 times.

The wiring 2 is formed on the substrate 1. In the present embodiment, the wiring 2 is arranged on the substrate 1. The wiring 2 includes a conductive material represented by metal such as Cu (copper), Ni (nickel), Fe (iron), Sn (tin), Ag (silver), Au (gold), etc. or an alloy thereof. A method of forming the wiring 2 is not particularly limited. For example, the wiring 2 is formed by plating.

As shown in FIGS. 1 to 7, the wiring 2 includes a first portion 21, a second portion 22, a first bonding portion 23, a second bonding portion 24, a first groove wiring 251, a second groove wiring 252, a third groove wiring 253, a fourth groove wiring 254, a third portion 26, and a fourth portion 27.

As shown in FIGS. 1 and 5, and the like, each of the first portion 21, the second portion 22, the first bonding portion 23, and the second bonding portion 24 is formed on the first main surface 11. In the present embodiment, the first bonding portion 23 is located at the center of the first main surface 11 in the first direction x and the center of the first main surface 11 in the second direction y. The first bonding portion 23 has a circular shape when viewed in the thickness direction z. The first bonding portion 23 is a portion to which the semiconductor light-emitting element 4 is die-bonded.

The first portion 21 is located on the second direction one side y1 in the first main surface 11. The first portion 21 extends along the first direction x from the first direction one side x1 end to the first direction other side x2 end in the first main surface 11. A part of the first portion 21 on the first direction one side x1 is in contact with both the first side surface 13 and the first concave groove 171. A part of the first portion 21 on the first direction other side x2 is in contact with both the second side surface 14 and the second concave groove 172. In the present embodiment, the first portion 21 has an extension portion 211 extending from the center in the first direction x to the second direction other side y2. As a result, the first portion 21 (the extension portion 211) is connected to the first bonding portion 23 on the first main surface 11.

The second portion 22 is located on the second direction other side y2 in the first main surface 11. The second portion 22 is separated from the first portion 21 on the first main surface 11. The second portion 22 extends along the first direction x from the first direction one side x1 end to the first direction other side x2 end in the first main surface 11. A part of the second portion 22 on the first direction one side x1 is in contact with both the first side surface 13 and the third concave groove 173. A part of the second portion 22 on the first direction other side x2 is in contact with both the second side surface 14 and the fourth concave groove 174. In the present embodiment, the second bonding portion 24 is located near the second direction other side y2 and near the first direction other side x2 in the first main surface 11. The second bonding portion 24 is separated from the first bonding portion 23 on the second direction other side y2 and the first direction other side x2. The second bonding portion 24 is a portion to which the wire 5 is bonded. In the present embodiment, a part of the second portion 22 near the first direction other side x2 is connected to the second bonding portion 24 on the first main surface 11.

As shown in FIGS. 2 to 7, the third portion 26 is formed in the second main surface 12. The third portion 26 is located on the second direction one side y1 in the second main surface 12. As shown in FIG. 4, the third portion 26 extends along the first direction x. A part of the third portion 26 on the first direction one side x1 is in contact with both the first side surface 13 and the first concave groove 171. A part of the third portion 26 on the first direction other side x2 is in contact with both the second side surface 14 and the second concave groove 172.

As shown in FIGS. 2 and 4 to 7, the fourth portion 27 is formed in the second main surface 12. The fourth portion 27 is located on the second direction other side y2 in the second main surface 12. As shown in FIG. 4, the fourth portion 27 extends along the first direction x. A part of the fourth portion 27 on the first direction one side x1 is in contact with both the first side surface 13 and the third concave groove 173. A part of the fourth portion 27 on the first direction other side x2 is in contact with both the second side surface 14 and the fourth concave groove 174.

As shown in FIGS. 1 to 4 and 6, the first groove wiring 251 is formed in the first concave groove 171. The first groove wiring 251 covers the entire first concave groove 171. The first groove wiring 251 is connected to both the first portion 21 and the third portion 26.

As shown in FIGS. 1, 3, 4, and 7, the second groove wiring 252 is formed in the second concave groove 172. The second groove wiring 252 covers the entire second concave groove 172. The second groove wiring 252 is connected to both the first portion 21 and the third portion 26.

As shown in FIGS. 1, 2, 4, and 6, the third groove wiring 253 is formed in the third concave groove 173. The third groove wiring 253 covers the entire third concave groove 173. The third groove wiring 253 is connected to both the second portion 22 and the fourth portion 27.

As shown in FIGS. 1, 4, and 7, the fourth groove wiring 254 is formed in the fourth concave groove 174. The fourth groove wiring 254 covers the entire fourth concave groove 174. The fourth groove wiring 254 is connected to both the second portion 22 and the fourth portion 27.

As shown in FIGS. 1, 2, and 5 to 7, the first insulating film 31 and the second insulating film 32 are formed on the first main surface 11 of the substrate 1. The specific configurations of the first insulating film 31 and the second insulating film 32 are not particularly limited. For example, the first insulating film 31 and the second insulating film 32 are formed by resist layers. In FIG. 1, for the sake of convenience of understanding, a region where the first insulating film 31 is formed and a region where the second insulating film 32 is formed are hatched.

The first insulating film 31 is located on the second direction one side y1 in the first main surface 11. The first insulating film 31 extends along the first direction x from the first direction one side x1 end to the first direction other side x2 end in the first main surface 11. The first insulating film 31 is formed across the first portion 21 (including the extension portion 211) and the first main surface 11. A portion of the first insulating film 31 is interposed between the first portion 21 and the sealing resin 6. The second insulating film 32 is located on the second direction other side y2 in the first main surface 11. The second insulating film 32 extends along the first direction x from the first direction one side x1 end to the first direction other side x2 end in the first main surface 11. The second insulating film 32 is formed across the second portion 22 and the first main surface 11. A portion of the second insulating film 32 is interposed between the second portion 22 and the sealing resin 6. By providing the above-described first insulating film 31 and second insulating film 32, when the semiconductor light-emitting device A1 is mounted on the mounting substrate, a bonding material such as solder is prevented from reaching the first bonding portion 23 and the second bonding portion 24 by moving along the surfaces of the first portion 21 and the second portion 22.

The semiconductor light-emitting element 4 is a light-emitting source of the semiconductor light-emitting device A1. The specific configuration of the semiconductor light-emitting element 4 is not particularly limited. For example, the semiconductor light-emitting element 4 is a light-emitting diode (LED) or a laser diode (LD). In the present embodiment, the semiconductor light-emitting element 4 is, for example, a light-emitting diode (LED). The number of semiconductor light-emitting elements included in the semiconductor light-emitting device of the present disclosure is not particularly limited, and may be two or more.

As shown in FIGS. 1 and 5, the semiconductor light-emitting element 4 includes an electrode 41 and an electrode 42. The electrode 41 is arranged on the thickness direction one side z1. The electrode 42 is arranged on the thickness direction other side z2. The electrode 42 is electrically bonded to the first bonding portion 23 by a bonding material 49. The bonding material 49 is, for example, a conductive bonding material such as solder or Ag paste. The semiconductor light-emitting element 4 mounted on the first bonding portion 23 in this way is arranged at the center of the substrate 1 (the center in each of the first direction x and the second direction y) when viewed in the thickness direction z.

The wire 5 is connected to the electrode 41 of the semiconductor light-emitting element 4 and the second bonding portion 24. The wire 5 is made of metal such as Au (gold). The electrode 41 of the semiconductor light-emitting element 4 is electrically bonded to the second bonding portion 24 by the wire 5.

The sealing resin 6 covers the semiconductor light-emitting element 4, the wire 5, and portions of the first main surface 11, the wiring 2, the first insulating film 31, and the second insulating film 32. More specifically, the sealing resin 6 covers the first bonding portion 23, the second bonding portion 24, and portions of the first portion 21 and the second portion 22, among the wiring 2. The sealing resin 6 is made of a material that transmits light from the semiconductor light-emitting element 4, such as transparent or translucent epoxy resin. The specific configuration of the sealing resin 6 is not particularly limited. In the present embodiment, as shown in FIGS. 2, 3, and 5 to 7, the sealing resin 6 has a top surface 61, two side surfaces 62, and two slant surfaces 63.

The top surface 61 is located on the thickness direction one side z1 and is a plane along the first direction x and the second direction y. The two side surfaces 62 are formed on the first direction one side x1 and the first direction other side x2, respectively, and are planes along the thickness direction z and the second direction y. The side surface 62 on the first direction one side x1 is flush (or substantially flush) with the first side surface 13 of the substrate 1. The side surface 62 on the first direction other side x2 is flush (or substantially flush) with the second side surface 14 of the substrate 1. The two slant surfaces 63 are formed on the second direction one side y1 and the second direction other side y2, respectively. The slant surfaces 63 are slant with respect to the thickness direction z.

As shown in FIGS. 2 and 4 to 6, the insulating film 7 is arranged on the second main surface 12 of the substrate 1. The specific configuration of the insulating film 7 is not particularly limited. For example, the insulating film 7 is formed by a resist layer. The insulating film 7 functions as a mark for determining a connection direction of the semiconductor light-emitting device A1. The insulating film 7 is arranged near the center of the first direction x in the second main surface 12 and between the third portion 26 and the fourth portion 27 in the second direction y. The insulating film 7 has a convex shape in which the fourth portion 27 side protrudes in the second direction y when viewed in the thickness direction z. The insulating film 7 having such a shape functions as a mark for determining the connection direction of the semiconductor light-emitting device A1.

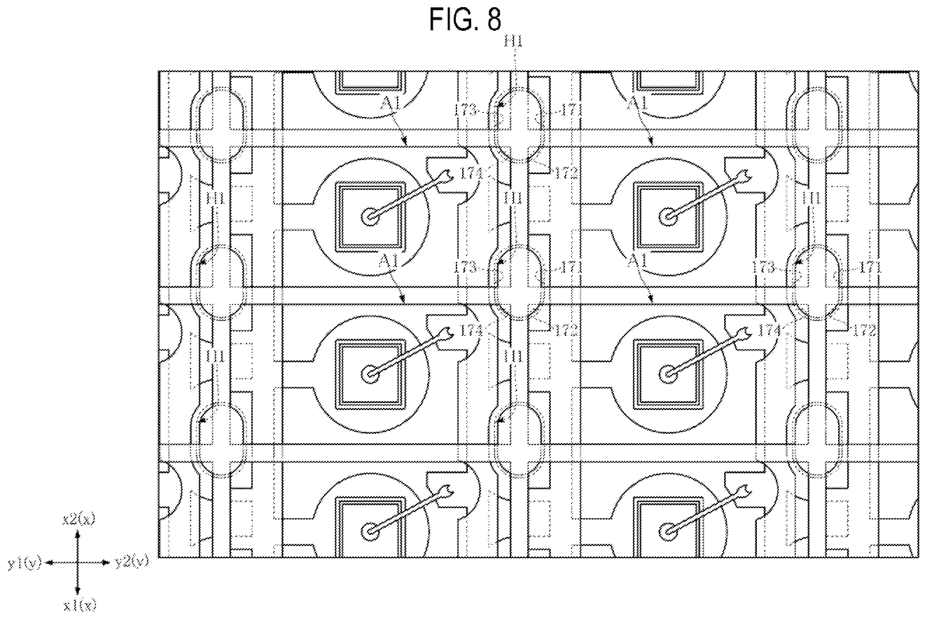

FIG. 8 is a plan view showing an example of a manufacturing process of the semiconductor light-emitting device A1. FIG. 8 shows an aspect in which a substrate material (plate material that is to be the substrate 1) is divided into a plurality of semiconductor light-emitting devices A1 by cutting along a plurality of cutting lines extending in the first direction x and the second direction y. A plurality of through-holes H1 are formed in the substrate material before cutting. The plurality of through-holes H1 are formed at predetermined intervals in each of the first direction x and the second direction y. Each through-hole H1 is an elongated hole which penetrates in the thickness direction z and whose longitudinal direction is the first direction x. The through-holes H1 are arranged to correspond to the four corners of the semiconductor light-emitting device A1. The cutting line extending in the first direction x passes through the center of the through-hole H1 in the second direction y. On the other hand, the cutting line extending in the second direction y passes through a position deviated from the center of the through-hole H1 in the first direction x toward the first direction one side x1. By cutting the substrate material in this way, the first concave groove 171, the second concave groove 172, the third concave groove 173, and the fourth concave groove 174 are formed at the four corners of the semiconductor light-emitting device A1.

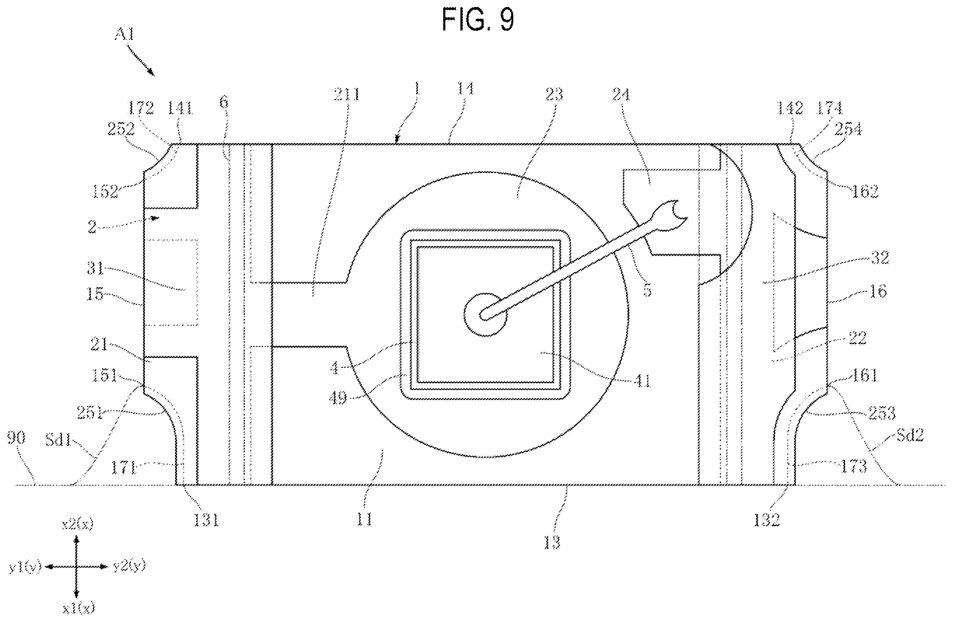

FIG. 9 is a front view showing an example of a state in which the semiconductor light-emitting device A1 is mounted on a mounting substrate. The semiconductor light-emitting device A1 is mounted on a mounting substrate 90 (represented by an imaginary line) in such a manner that the first side surface 13 (the surface facing the first direction one side x1) of the substrate 1 faces the mounting substrate 90. The semiconductor light-emitting device A1 is used as a side-view type light source that emits light in a direction parallel to the front surface of the mounting substrate 90. For example, a wiring pattern (not shown) is formed on the front surface of the mounting substrate 90. The semiconductor light-emitting device A1 is mounted on the mounting substrate 90 via a bonding portion such as solder. Each of the first groove wiring 251, the first portion 21, the third portion 26 (not shown), the third groove wiring 253, the second portion 22, and the fourth portion 27 (not shown) is bonded to the mounting substrate 90 by a bonding portion. In FIG. 9, a bonding portion Sd1 and a bonding portion Sd2 are represented by imaginary lines. The bonding portion Sd1 bonds the first groove wiring 251 and the mounting substrate 90. The bonding portion Sd2 bonds the third groove wiring 253 and the mounting substrate 90.

Next, an operation of the semiconductor light-emitting device A1 of the present embodiment will be described.

The semiconductor light-emitting device A1 includes the wiring 2 formed on the substrate 1, and the semiconductor light-emitting element 4 supported on the first main surface 11 of the substrate 1. The substrate 1 includes the first side surface 13, the second side surface 14, the third side surface 15, and the first concave groove 171. The first side surface 13 faces the first direction one side x1, the second side surface 14 faces the first direction other side x2, and the third side surface 15 faces the second direction one side y1. The first concave groove 171 is formed between the first side surface 13 and the third side surface 15 and is recessed from the first side surface 13 and the third side surface 15. The first side surface 13 has the first edge 131. The first edge 131 is located on the second direction one side y1 of the first side surface 13 and is in contact with the first concave groove 171. The second side surface 14 has the second edge 141 located on the second direction one side y1. The third side surface 15 has the third edge 151 and the fourth edge 152. The third edge 151 is located on the first direction one side x1 of the third side surface 15 and is in contact with the first concave groove 171. The fourth edge 152 is located on the first direction other side x2 of the third side surface 15. The wiring 2 includes the first groove wiring 251 formed in the first concave groove 171. The distance (the first distance D1) between the first edge 131 of the first side surface 13 and the third edge 151 of the third side surface 15 is larger than the distance (the second distance D2) between the second edge 141 of the second side surface 14 and the fourth edge 152 of the third side surface 15.

According to such a configuration, it is possible to secure a large dimension of the first concave groove 171 corresponding to the distance (the first distance D1) between the first edge 131 and the third edge 151. As a result, as shown in FIG. 9, when the semiconductor light-emitting device A1 is mounted on the mounting substrate 90, the first groove wiring 251 formed in the first concave groove 171 is bonded to the mounting substrate 90 via a bonding portion Sd1 of a sufficient size. This makes it possible to increase the mounting strength of the semiconductor light-emitting device A1 while reducing the size of the semiconductor light-emitting device A1.

In the first concave groove 171, the first dimension L1, which is the depth dimension from the first side surface 13 to the first direction other side x2, is larger than the second dimension L2 which is the depth dimension from the third side surface 15 to the second direction other side y2. The bonding portion Sd1 bonded to the first groove wiring 251 is formed in a range corresponding to the first dimension L1 of the first concave groove 171. When the first dimension L1 is larger than the second dimension L2 as described above, it is possible to secure a large dimension of the bonding portion Sd1 in the first direction x. This may increase the mounting strength of the semiconductor light-emitting device A1.

The substrate 1 includes the second concave groove 172. The second concave groove 172 is formed between the second side surface 14 and the third side surface 15 and is recessed from the second side surface 14 and the third side surface 15. Each of the second edge 141 of the second side surface 14 and the fourth edge 152 of the third side surface 15 is in contact with the second concave groove 172. Further, the first dimension L1 (the depth dimension from the first side surface 13 to the first direction other side x2 in the first concave groove 171) is larger than the third dimension L3 which is the depth dimension from the second side surface 14 to the first direction one side x1 in the second concave groove 172. The first concave groove 171 and the second concave groove 172 having such a dimensional relationship may be formed by cutting the through-holes of a predetermined shape formed in the substrate material at appropriate positions, as described with reference to FIG. 8. Further, when the semiconductor light-emitting device A1 is mounted on the mounting substrate 90, it is possible to easily recognize the first side surface 13 facing the mounting substrate 90 in appearance from a difference in the dimensions of the first concave groove 171 and the second concave groove 172.

The substrate 1 includes the fourth side surface 16 and the third concave groove 173. The fourth side surface 16 faces the second direction other side y2. The third concave groove 173 is formed between the first side surface 13 and the fourth side surface 16 and is recessed from the first side surface 13 and the fourth side surface 16. The first side surface 13 has the fifth edge 132. The fifth edge 132 is located on the second direction other side y2 of the first side surface 13 and is in contact with the third concave groove 173. The second side surface 14 has the sixth edge 142 located on the second direction other side y2. The fourth side surface 16 has the seventh edge 161 and the eighth edge 162. The seventh edge 161 is located on the first direction one side x1 of the fourth side surface 16 and is in contact with the third concave groove 173. The eighth edge 162 is located on the first direction other side x2 of the fourth side surface 16. The wiring 2 includes the third groove wiring 253 formed in the third concave groove 173. The distance (the third distance D3) between the fifth edge 132 of the first side surface 13 and the seventh edge 161 of the fourth side surface 16 is larger than the distance (the fourth distance D4) between the sixth edge 142 of the second side surface 14 and the eighth edge 162 of the fourth side surface 16.

According to such a configuration, it is possible to secure a large dimension of the third concave groove 173 corresponding to the distance (the third distance D3) between the fifth edge 132 and the seventh edge 161. As a result, as shown in FIG. 9, when the semiconductor light-emitting device A1 is mounted on the mounting substrate 90, the third groove wiring 253 formed in the third concave groove 173 is bonded to the mounting substrate 90 via a bonding portion Sd2 of a sufficient size. This makes it possible to increase the mounting strength of the semiconductor light-emitting device A1 while reducing the size of the semiconductor light-emitting device A1.

In the third concave groove 173, the fourth dimension L4, which is the depth dimension from the first side surface 13 to the first direction other side x2, is larger than the fifth dimension L5 which is the depth dimension from the fourth side surface 16 to the second direction one side y1. The bonding portion Sd2 bonded to the third groove wiring 253 is formed in a range corresponding to the fourth dimension L4 of the third concave groove 173. When the fourth dimension L4 is larger than the fifth dimension L5 as described above, it is possible to secure a large dimension of the bonding portion Sd2 in the first direction x. This may increase the mounting strength of the semiconductor light-emitting device A1.

The substrate 1 includes the fourth concave groove 174. The fourth concave groove 174 is formed between the second side surface 14 and the fourth side surface 16 and is recessed from the second side surface 14 and the fourth side surface 16. Each of the sixth edge 142 of the second side surface 14 and the eighth edge 162 of the fourth side surface 16 is in contact with the fourth concave groove 174. Further, the fourth dimension L4 (the depth dimension from the first side surface 13 to the first direction other side x2 in the third concave groove 173) is larger than the sixth dimension L6 which is the depth dimension from the second side surface 14 to the first direction one side x1 in the fourth concave groove 174. The third concave groove 173 and the fourth concave groove 174 having such a dimensional relationship may be formed by cutting the through-holes of a predetermined shape formed in the substrate material at appropriate positions, as described with reference to FIG. 8. Further, when the semiconductor light-emitting device A1 is mounted on the mounting substrate 90, it is possible to easily recognize the first side surface 13 facing the mounting substrate 90 in appearance from a difference in the dimensions of the third concave groove 173 and the fourth concave groove 174.

### Second Embodiment

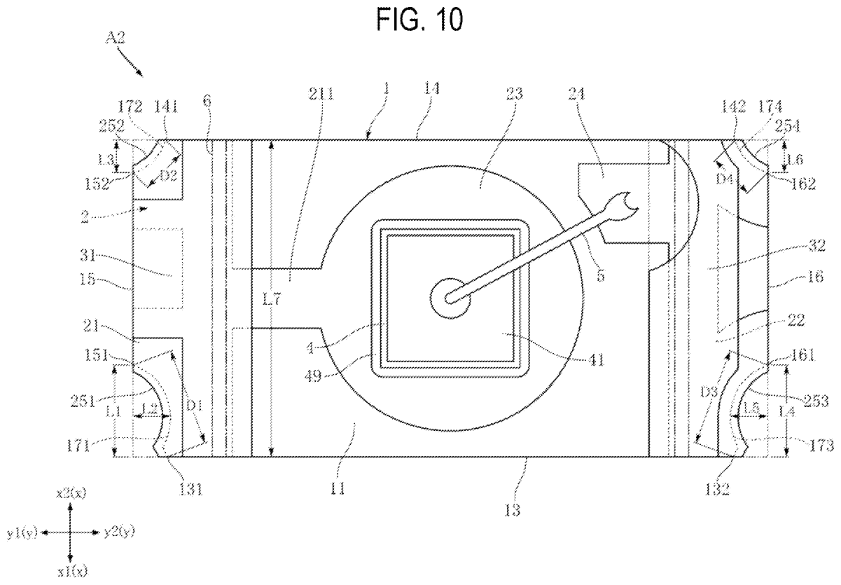

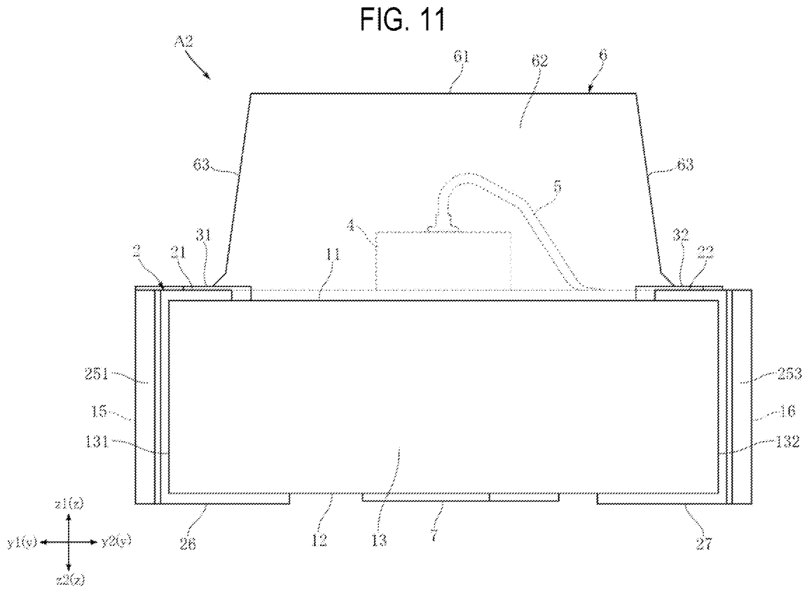

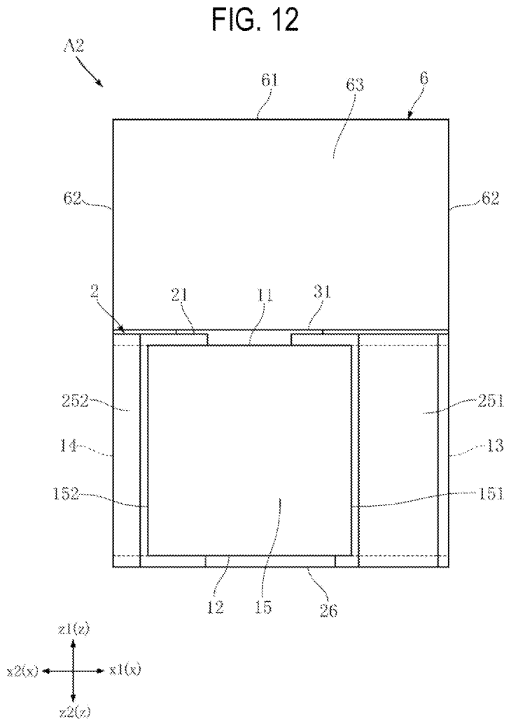

FIGS. 10 to 12 show a semiconductor light-emitting device according to a second embodiment of the present disclosure. FIG. 10 is a plan view of a semiconductor light-emitting device A2 of the present embodiment. FIG. 11 is a front view of the semiconductor light-emitting device A2. FIG. 12 is a left side view of the semiconductor light-emitting device A2. For the sake of convenience of understanding, FIG. 10 is shown as penetrating the sealing resin 6. In FIG. 10 and subsequent figures, elements that are the same as or similar to those of the semiconductor light-emitting device A1 in the above-described embodiments are denoted by the same reference numerals as those of the above-described embodiments, and explanation thereof will not be repeated as appropriate. In addition, configurations of the respective components in the respective embodiments may be appropriately combined with one another as long as there is no technical contradiction.

In the semiconductor light-emitting device A2 of the present embodiment, shapes of the first concave groove 171 and the third concave groove 173 formed in the substrate 1 are different from those of the above-described embodiments. In the present embodiment, a cross-sectional shape of the first concave groove 171 perpendicular to a thickness direction z is a shape in which two circular arcs with different central angles are connected. Further, like the first concave groove 171, a cross-sectional shape of the third concave groove 173 perpendicular to the thickness direction z is a shape in which two circular arcs with different central angles are connected.

In the present embodiment, in the example shown in FIG. 10, a ratio of the depth dimension (the first dimension L1) of the first concave groove 171, from the first side surface 13 to the first direction other side x2, to the length (the seventh dimension L7) of the first main surface 11 in the first direction x is about 0.29 times. Further, a ratio of the depth dimension (the fourth dimension L4) of the third concave groove 173, from the first side surface 13 to the first direction other side x2, to the seventh dimension L7 is about 0.29 times.

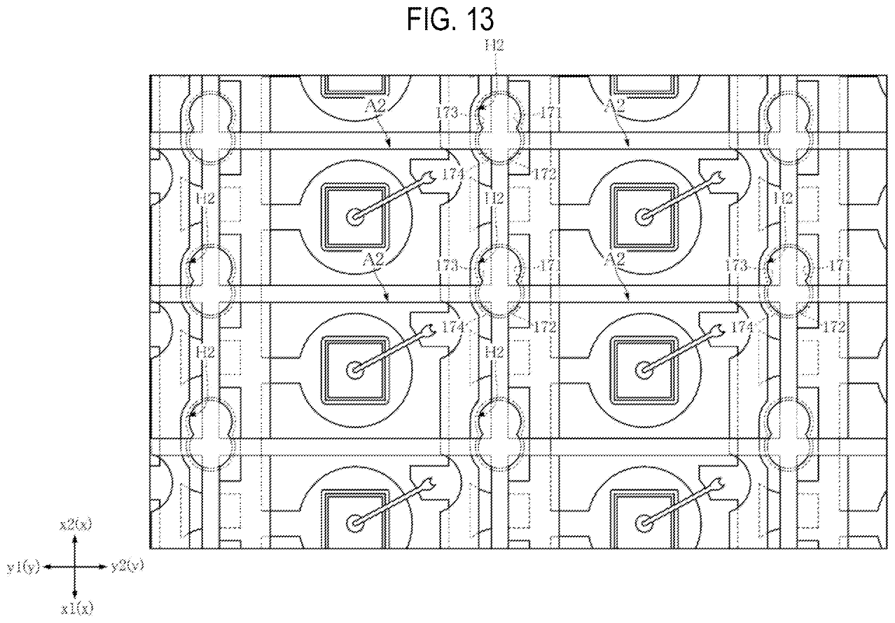

FIG. 13 is a plan view showing an example of a manufacturing process of the semiconductor light-emitting device A2. FIG. 13 shows an aspect in which a substrate material (plate material that is to be the substrate 1) is divided into a plurality of semiconductor light-emitting devices A2 by cutting along a plurality of cutting lines respectively extending in the first direction x and the second direction y. A plurality of through-holes H2 are formed in the substrate material before cutting. The plurality of through-holes H2 are formed at predetermined intervals in each of the first direction x and the second direction y. Each through-hole H2 penetrates in the thickness direction z and has a shape in which two circular holes partially overlap each other. The through-holes H2 are elongated in the first direction x when viewed in the thickness direction z. The through-holes H2 are arranged to correspond to the four corners of the semiconductor light-emitting device A2. The cutting line extending in the first direction x passes through the center of the through-hole H2 in the second direction y. On the other hand, the cutting line extending in the second direction y passes through a position deviated from the center of the through-hole H2 in the first direction x toward the first direction one side x1. By cutting the substrate material in this way, the first concave groove 171, the second concave groove 172, the third concave groove 173, and the fourth concave groove 174 are formed at the four corners of the semiconductor light-emitting device A2.

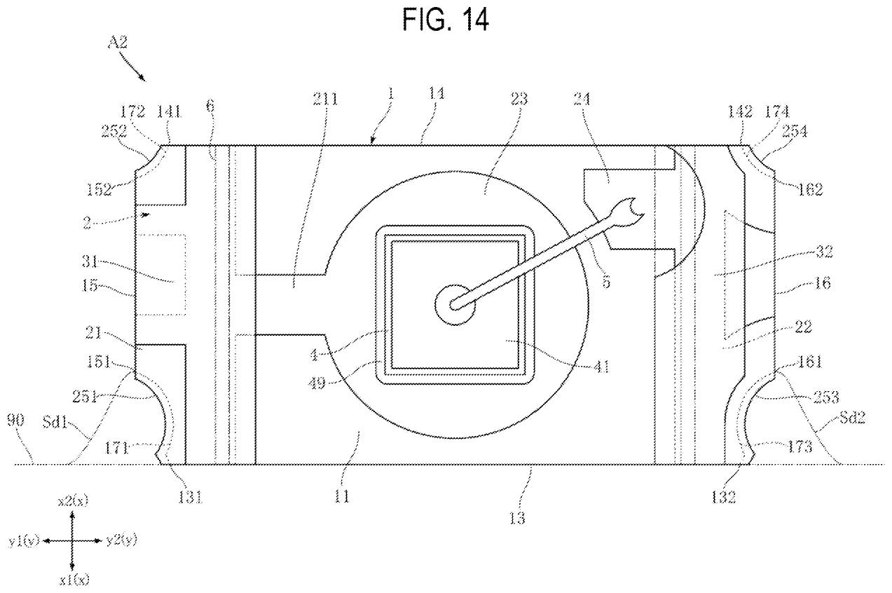

FIG. 14 is a front view showing an example of a state in which the semiconductor light-emitting device A2 is mounted on a mounting substrate. The semiconductor light-emitting device A2 is mounted on a mounting substrate 90 (represented by an imaginary line) in such a manner that the first side surface 13 (the surface facing the first direction one side x1) of the substrate 1 faces the mounting substrate 90.

In the semiconductor light-emitting device A2 of the present embodiment, the substrate 1 includes the first side surface 13, the second side surface 14, the third side surface 15, and the first concave groove 171. The first concave groove 171 is formed between the first side surface 13 and the third side surface 15 and is recessed from the first side surface 13 and the third side surface 15. The distance (the first distance D1) between the first edge 131 of the first side surface 13 and the third edge 151 of the third side surface 15 is larger than the distance (the second distance D2) between the second edge 141 of the second side surface 14 and the fourth edge 152 of the third side surface 15. According to such a configuration, it is possible to secure a large dimension of the first concave groove 171 corresponding to the distance (the first distance D1) between the first edge 131 and the third edge 151. As a result, as shown in FIG. 14, when the semiconductor light-emitting device A2 is mounted on the mounting substrate 90, the first groove wiring 251 formed in the first concave groove 171 is bonded to the mounting substrate 90 via a bonding portion Sd1 of a sufficient size. This makes it possible to increase the mounting strength of the semiconductor light-emitting device A2 while reducing the size of the semiconductor light-emitting device A2.

The substrate 1 includes the fourth side surface 16 and the third concave groove 173. The third concave groove 173 is formed between the first side surface 13 and the fourth side surface 16 and is recessed from the first side surface 13 and the fourth side surface 16. The distance (the third distance D3) between the fifth edge 132 of the first side surface 13 and the seventh edge 161 of the fourth side surface 16 is larger than the distance (the fourth distance D4) between the sixth edge 142 of the second side surface 14 and the eighth edge 162 of the fourth side surface 16. According to such a configuration, it is possible to secure a large dimension of the third concave groove 173 corresponding to the distance (the third distance D3) between the fifth edge 132 and the seventh edge 161. As a result, as shown in FIG. 14, when the semiconductor light-emitting device A2 is mounted on the mounting substrate 90, the third groove wiring 253 formed in the third concave groove 173 is bonded to the mounting substrate 90 via a bonding portion Sd2 of a sufficient size. This makes it possible to increase the mounting strength of the semiconductor light-emitting device A2 while reducing the size of the semiconductor light-emitting device A2. In addition, the same effects as those of the above-described embodiments may be obtained within the range of the configuration similar to that of the semiconductor light-emitting device A1 of the above-described embodiments.

### Third Embodiment

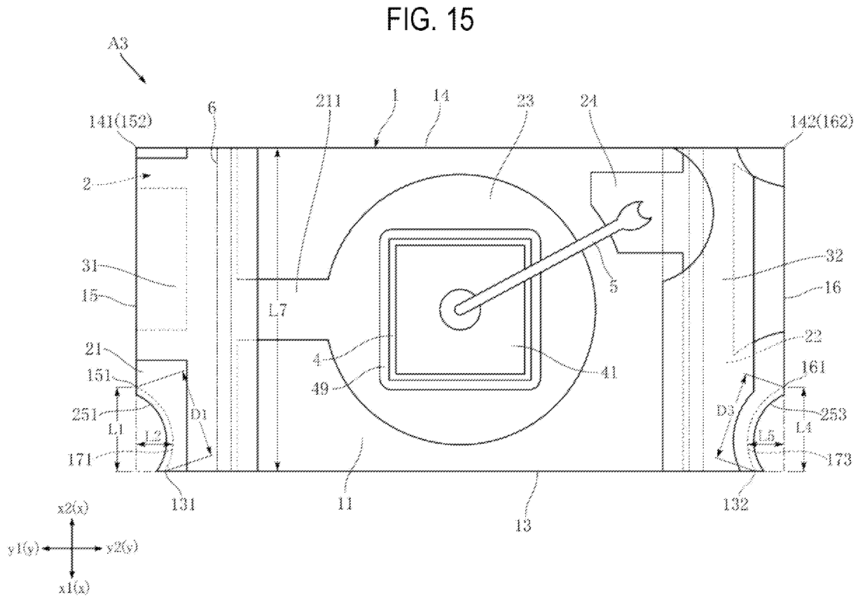

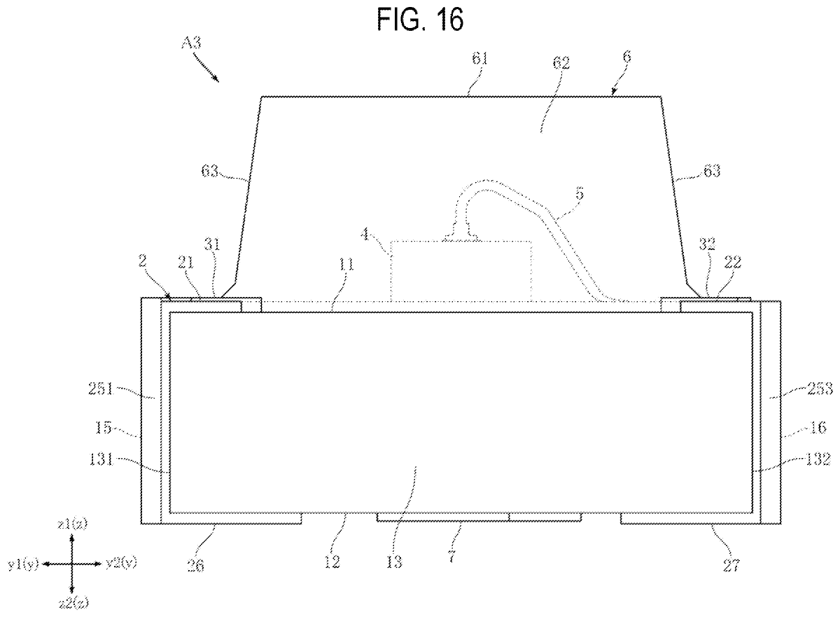

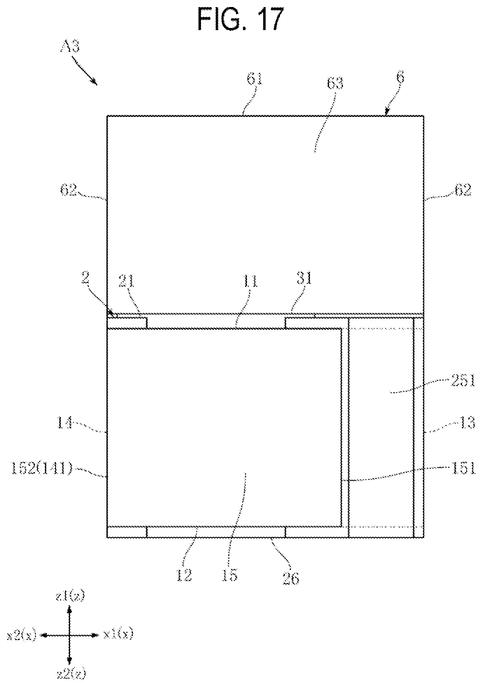

FIGS. 15 to 17 show a semiconductor light-emitting device according to a third embodiment of the present disclosure. FIG. 15 is a plan view of a semiconductor light-emitting device A3 of the present embodiment. FIG. 16 is a front view of the semiconductor light-emitting device A3. FIG. 17 is a left side view of the semiconductor light-emitting device A3. FIG. 15 is shown as penetrating the sealing resin 6 for the sake of convenience of understanding.

In the semiconductor light-emitting device A3 of the present embodiment, shapes of the first concave groove 171 and the third concave groove 173 formed in the substrate 1 are different from those of the above-described embodiments. In the present embodiment, a cross-sectional shape of the first concave groove 171 perpendicular to the thickness direction z is a circular arc shape. Further, the cross-sectional shape of the third concave groove 173 perpendicular to the thickness direction z is also a circular arc shape, like the first concave groove 171.

In the present embodiment, unlike the above-described embodiments, the second concave groove 172 and the fourth concave groove 174 are not provided at the two corners of the substrate 1. Since the second concave groove 172 is not provided, the second edge 141 located on the second direction one side y1 in the second side surface 14 coincides with the fourth edge 152 located on the first direction other side x2 in the third side surface 15. Therefore, the distance (the second distance) between the second edge 141 of the second side surface 14 and the fourth edge 152 of the third side surface 15 is zero. Further, since the fourth concave groove 174 is not provided, the sixth edge 142 located on the second direction other side y2 in the second side surface 14 coincides with the eighth edge 162 located on the first direction other side x2 in the fourth side surface 16. Therefore, the distance (the fourth distance) between the sixth edge 142 of the second side surface 14 and the eighth edge 162 of the fourth side surface 16 is zero.

In the present embodiment, in the example shown in FIG. 15, a ratio of the depth dimension (the first dimension L1) of the first concave groove 171, from the first side surface 13 to the first direction other side x2, to the length (the seventh dimension L7) of the first main surface 11 in the first direction x is about 0.26 times. Further, a ratio of the depth dimension (the fourth dimension L4) of the third concave groove 173, from the first side surface 13 to the first direction other side x2, to the seventh dimension L7 is about 0.26 times.

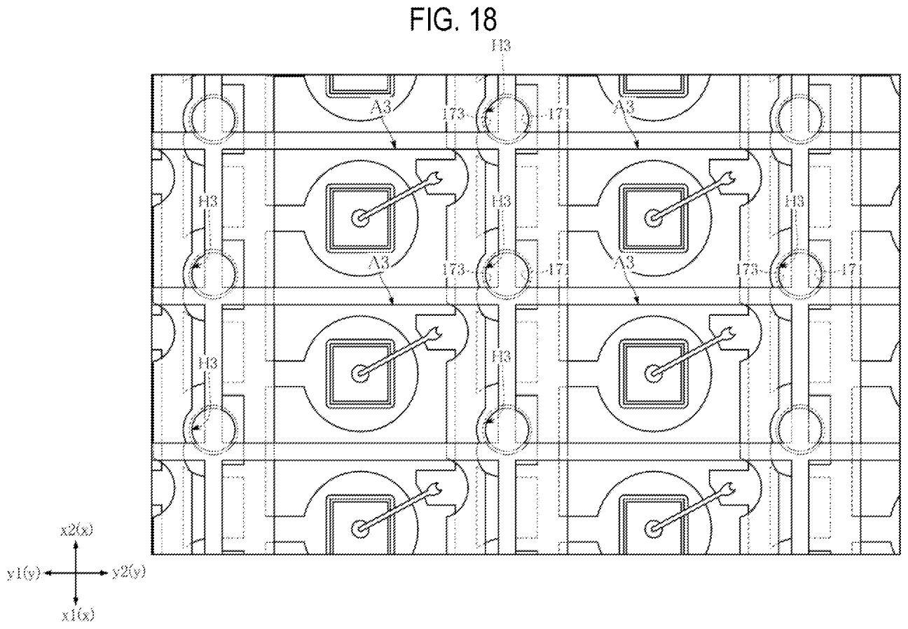

FIG. 18 is a plan view showing an example of a manufacturing process of the semiconductor light-emitting device A3. FIG. 18 shows an aspect in which a substrate material (plate material that is to be the substrate 1) is divided into a plurality of semiconductor light-emitting devices A3 by cutting along a plurality of cutting lines respectively extending in the first direction x and the second direction y. A plurality of through-holes H3 are formed in the substrate material before cutting. The plurality of through-holes H3 are formed at predetermined intervals in each of the first direction x and the second direction y. Each through-hole H3 penetrates in the thickness direction z and has a circular shape. The through-holes H3 are arranged near the four corners of the semiconductor light-emitting device A3. The cutting line extending in the first direction x passes through the center of the through-hole H3 in the second direction y. On the other hand, the cutting line extending in the second direction y passes through a position deviated from the center of the through-hole H3 in the first direction x toward the first direction one side x1. By cutting the substrate material in this way, the first concave groove 171 and the third concave groove 173 are formed at the two corners of the semiconductor light-emitting device A3.

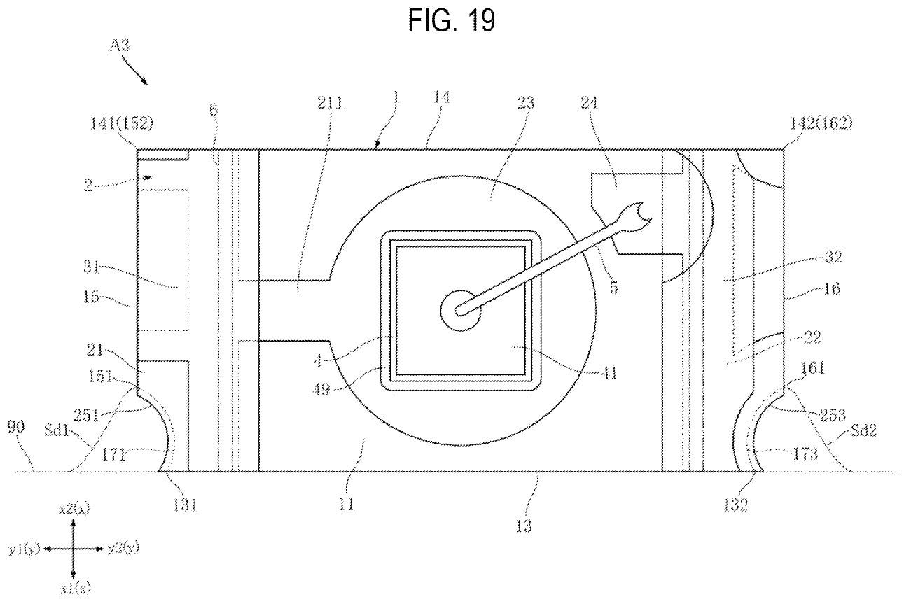

FIG. 19 is a front view showing an example of a state in which the semiconductor light-emitting device A3 is mounted on a mounting substrate. The semiconductor light-emitting device A3 is mounted on a mounting substrate 90 (represented by an imaginary line) in such a manner that the first side surface 13 (the surface facing the first direction one side x1) of the substrate 1 faces the mounting substrate 90.

In the semiconductor light-emitting device A3 of the present embodiment, the substrate 1 includes the first side surface 13, the second side surface 14, the third side surface 15, and the first concave groove 171. The first concave groove 171 is formed between the first side surface 13 and the third side surface 15 and is recessed from the first side surface 13 and the third side surface 15. The distance (the first distance D1) between the first edge 131 of the first side surface 13 and the third edge 151 of the third side surface 15 is larger than the distance (the second distance) between the second edge 141 of the second side surface 14 and the fourth edge 152 of the third side surface 15. According to such a configuration, it is possible to secure a large dimension of the first concave groove 171 corresponding to the distance (the first distance D1) between the first edge 131 and the third edge 151. As a result, as shown in FIG. 19, when the semiconductor light-emitting device A3 is mounted on the mounting substrate 90, the first groove wiring 251 formed in the first concave groove 171 is bonded to the mounting substrate 90 via a bonding portion Sd1 of a sufficient size. This makes it possible to increase the mounting strength of the semiconductor light-emitting device A3 while reducing the size of the semiconductor light-emitting device A3.

The substrate 1 includes the fourth side surface 16 and the third concave groove 173. The third concave groove 173 is formed between the first side surface 13 and the fourth side surface 16 and is recessed from the first side surface 13 and the fourth side surface 16. The distance (the third distance D3) between the fifth edge 132 of the first side surface 13 and the seventh edge 161 of the fourth side surface 16 is larger than the distance (the fourth distance) between the sixth edge 142 of the second side surface 14 and the eighth edge 162 of the fourth side surface 16. According to such a configuration, it is possible to secure a large dimension of the third concave groove 173 corresponding to the distance (the third distance D3) between the fifth edge 132 and the seventh edge 161. As a result, as shown in FIG. 19, when the semiconductor light-emitting device A3 is mounted on the mounting substrate 90, the third groove wiring 253 formed in the third concave groove 173 is bonded to the mounting substrate 90 via a bonding portion Sd2 of a sufficient size. This makes it possible to increase the mounting strength of the semiconductor light-emitting device A3 while reducing the size of the semiconductor light-emitting device A3. In addition, the same effects as those of the above-described embodiment may be obtained within the range of the configuration similar to that of the semiconductor light-emitting device A1 of the above-described embodiment.

The semiconductor light-emitting device according to the present disclosure is not limited to the above-described embodiments. The specific configuration of each component of the semiconductor light-emitting device according to the present disclosure may be changed in design in various ways.

The present disclosure includes configurations related to the following Supplementary Notes.

[Supplementary Note 1]

A semiconductor light-emitting device including:
a substrate:
a wiring formed on the substrate; and
a semiconductor light-emitting element,
wherein the substrate has a first main surface facing one side in a thickness direction of the substrate, a second main surface facing the other side in the thickness direction, a first side surface facing one side in a first direction orthogonal to the thickness direction, a second side surface facing the other side in the first direction, a third side surface facing one side in a second direction orthogonal to both the thickness direction and the first direction, and a first concave groove formed between the first side surface and the third side surface and recessed from the first side surface and the third side surface,
wherein the first side surface has a first edge located on the one side in the second direction and in contact with the first concave groove,
wherein the second side surface has a second edge located on the one side in the second direction,
wherein the third side surface has a third edge located on the one side in the first direction and in contact with the first concave groove, and a fourth edge located on the other side in the first direction,
wherein the semiconductor light-emitting device is supported on the first main surface,
wherein the wiring includes a first groove wiring formed in the first concave groove, and
wherein a first distance between the first edge and the third edge is larger than a second distance between the second edge and the fourth edge.

[Supplementary Note 2]

The semiconductor light-emitting device of Supplementary Note 1, wherein, in the first concave groove, a first dimension, which is a depth dimension from the first side surface to the other side in the first direction, is larger than a second dimension which is a depth dimension from the third side surface to the other side in the second direction.

[Supplementary Note 3]

The semiconductor light-emitting device of Supplementary Note 2, wherein the substrate includes a second concave groove formed between the second side surface and the third side surface and recessed from the second side surface and the third side surface, and
wherein each of the second edge and the fourth edge is in contact with the second concave groove.

[Supplementary Note 4]

The semiconductor light-emitting device of Supplementary Note 3, wherein the first dimension is larger than a third dimension which is a depth dimension from the second side surface to the one side in the first direction in the second concave groove.

[Supplementary Note 5]

The semiconductor light-emitting device of Supplementary Note 1 or 2, wherein the second edge coincides with the fourth edge.

[Supplementary Note 6]

The semiconductor light-emitting device of any one of Supplementary Notes 1 to 5, wherein the substrate has a fourth side surface facing the other side in the second direction, and a third concave groove formed between the first side surface and the fourth side surface and recessed from the first side surface and the fourth side surface,
wherein the first side surface has a fifth edge located on the other side in the second direction and in contact with the third concave groove,
wherein the second side surface has a sixth edge located on the other side in the second direction,
wherein the fourth side surface has a seventh edge located on the one side in the first direction and in contact with the third concave groove, and an eighth edge located on the other side in the first direction,
wherein the wiring includes a third groove wiring formed in the third concave groove, and
wherein a third distance, which is a distance between the fifth edge and the seventh edge, is larger than a fourth distance which is a distance between the sixth edge and the eighth edge.

[Supplementary Note 7]

The semiconductor light-emitting device of Supplementary Note 6, wherein, in the third concave groove, a fourth dimension, which is a depth dimension from the first side surface to the other side in the first direction, is larger than a fifth dimension which is a depth dimension from the fourth side surface to the one side in the second direction.

[Supplementary Note 8]

The semiconductor light-emitting device of Supplementary Note 7, wherein the substrate has a fourth concave groove formed between the second side surface and the fourth side surface and recessed from the second side surface and the fourth side surface, and
wherein each of the sixth edge and the eighth edge is in contact with the fourth concave groove.

[Supplementary Note 9]

The semiconductor light-emitting device of Supplementary Note 8, wherein the fourth dimension is larger than a sixth dimension which is a depth dimension from the second side surface to the one side in the first direction in the fourth concave groove.

[Supplementary Note 10]

The semiconductor light-emitting device of Supplementary Note 6 or 7, wherein the sixth edge coincides with the eighth edge.

[Supplementary Note 11]

The semiconductor light-emitting device of any one of Supplementary Notes 6 to 10, wherein the wiring includes a first bonding portion and a second bonding portion each formed on the first main surface,
wherein the first bonding portion is electrically bonded to the semiconductor light-emitting element, and
wherein the second bonding portion is separated from the first bonding portion on the first main surface and electrically bonded to the semiconductor light-emitting element.

[Supplementary Note 12]

The semiconductor light-emitting device of Supplementary Note 11, wherein the second bonding portion is located near the other side in the first direction in the first main surface, and
wherein the semiconductor light-emitting element is electrically bonded to the second bonding portion via a wire.

[Supplementary Note 13]

The semiconductor light-emitting device of Supplementary Note 11 or 12, wherein the semiconductor light-emitting element is arranged on the first bonding portion.

[Supplementary Note 14]

The semiconductor light-emitting device of any one of Supplementary Notes 11 to 13, wherein the wiring includes a first portion and a second portion each formed on the first main surface,
wherein the first portion is connected to both the first bonding portion and the first groove wiring, and
wherein the second portion is separated from the first portion on the first main surface and connected to both the second bonding portion and the third groove wiring.

[Supplementary Note 15]

The semiconductor light-emitting device of any one of Supplementary Notes 1 to 14, further including: a sealing resin supported by the first main surface and covering the semiconductor light-emitting element.

According to the present disclosure in some embodiments, it is possible to increase the mounting strength of a semiconductor light-emitting device and reduce the size of the device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor light-emitting device comprising:
a substrate;
a wiring formed on the substrate; and
a semiconductor light-emitting element,
wherein the substrate has a first main surface facing one side in a thickness direction of the substrate, a second main surface facing the other side in the thickness direction, a first side surface facing one side in a first direction orthogonal to the thickness direction, a second side surface facing the other side in the first direction, a third side surface facing one side in a second direction orthogonal to both the thickness direction and the first direction, and a first concave groove formed between the first side surface and the third side surface and recessed from the first side surface and the third side surface,
wherein the first side surface has a first edge located on the one side in the second direction and in contact with the first concave groove,
wherein the second side surface has a second edge located on the one side in the second direction,
wherein the third side surface has a third edge located on the one side in the first direction and in contact with the first concave groove, and a fourth edge located on the other side in the first direction,
wherein the semiconductor light-emitting device is supported on the first main surface,
wherein the wiring includes a first groove wiring formed in the first concave groove, and
wherein a first distance between the first edge and the third edge is larger than a second distance between the second edge and the fourth edge.

2. The semiconductor light-emitting device of claim 1, wherein, in the first concave groove, a first dimension, which is a depth dimension from the first side surface to the other side in the first direction, is larger than a second dimension which is a depth dimension from the third side surface to the other side in the second direction.

3. The semiconductor light-emitting device of claim 2, wherein the substrate includes a second concave groove formed between the second side surface and the third side surface and recessed from the second side surface and the third side surface, and
wherein each of the second edge and the fourth edge is in contact with the second concave groove.

4. The semiconductor light-emitting device of claim 3, wherein the first dimension is larger than a third dimension which is a depth dimension from the second side surface to the one side in the first direction in the second concave groove.

5. The semiconductor light-emitting device of claim 1, wherein the second edge coincides with the fourth edge.

6. The semiconductor light-emitting device of claim 1, wherein the substrate has a fourth side surface facing the other side in the second direction, and a third concave groove formed between the first side surface and the fourth side surface and recessed from the first side surface and the fourth side surface,
wherein the first side surface has a fifth edge located on the other side in the second direction and in contact with the third concave groove,
wherein the second side surface has a sixth edge located on the other side in the second direction,
wherein the fourth side surface has a seventh edge located on the one side in the first direction and in contact with the third concave groove, and an eighth edge located on the other side in the first direction,
wherein the wiring includes a third groove wiring formed in the third concave groove, and
wherein a third distance, which is a distance between the fifth edge and the seventh edge, is larger than a fourth distance which is a distance between the sixth edge and the eighth edge.

7. The semiconductor light-emitting device of claim 6, wherein, in the third concave groove, a fourth dimension, which is a depth dimension from the first side surface to the other side in the first direction, is larger than a fifth dimension which is a depth dimension from the fourth side surface to the one side in the second direction.

8. The semiconductor light-emitting device of claim 7, wherein the substrate has a fourth concave groove formed between the second side surface and the fourth side surface and recessed from the second side surface and the fourth side surface, and
wherein each of the sixth edge and the eighth edge is in contact with the fourth concave groove.

9. The semiconductor light-emitting device of claim 8, wherein the fourth dimension is larger than a sixth dimension which is a depth dimension from the second side surface to the one side in the first direction in the fourth concave groove.

10. The semiconductor light-emitting device of claim 6, wherein the sixth edge coincides with the eighth edge.

11. The semiconductor light-emitting device of claim 6, wherein the wiring includes a first bonding portion and a second bonding portion each formed on the first main surface,
wherein the first bonding portion is electrically bonded to the semiconductor light-emitting element, and
wherein the second bonding portion is separated from the first bonding portion on the first main surface and electrically bonded to the semiconductor light-emitting element.

12. The semiconductor light-emitting device of claim 11, wherein the second bonding portion is located near the other side in the first direction in the first main surface, and
wherein the semiconductor light-emitting element is electrically bonded to the second bonding portion via a wire.

13. The semiconductor light-emitting device of claim 11, wherein the semiconductor light-emitting element is arranged on the first bonding portion.

14. The semiconductor light-emitting device of claim 11, wherein the wiring includes a first portion and a second portion each formed on the first main surface,
wherein the first portion is connected to both the first bonding portion and the first groove wiring, and
wherein the second portion is separated from the first portion on the first main surface and connected to both the second bonding portion and the third groove wiring.

15. The semiconductor light-emitting device of claim 1, further comprising a sealing resin supported by the first main surface and covering the semiconductor light-emitting element.
